(19) United States
(12) Patent Application Publication
(10) Pub. No.: US 2025/0386602 A1
(43) Pub. Date: Dec. 18, 2025

(54) SOLID-STATE IMAGING DEVICE

(71) Applicant: SONY SEMICONDUCTOR SOLUTIONS CORPORATION, KANAGAWA (JP)

(72) Inventor: TAKAHIRO YADA, KUMAMOTO (JP)

(21) Appl. No.: 18/878,927

(22) PCT Filed: May 22, 2023
(86) PCT No.: PCT/JP2023/018943

§ 371 Date: Dec. 26, 2024

(30) Foreign Application Priority Data
Jul. 14, 2022 (JP) 2022-113489

(51) Int. Cl. H10F 39/18; H10F 39/00

(52) U.S. Cl. CPC H10F 39/182; H10F 39/804; H10F 39/811

(57) ABSTRACT

Provided is a solid-state imaging device capable of suppressing cracking or peeling of a cover glass. A solid-state imaging device according to the present disclosure includes: a photoelectric conversion element that has a light receiving surface; a glass member that is provided above the light receiving surface; and a first resin member that covers a side surface of the photoelectric conversion element and a side surface of the glass member. An area of the photoelectric conversion element is 59 mm² or more in a plan view viewed from a first direction substantially perpendicular to the light receiving surface, the glass member protrudes from the photoelectric conversion element by a first width of 15% to 93% of a width of the first resin member in a second direction substantially parallel to the light receiving surface, and a thickness of the glass member is 40% or more of a thickness of the first resin member in the first direction.

### TECHNICAL FIELD

The present disclosure relates to a solid-state imaging device.

### BACKGROUND ART

A solid-state imaging device such as a complementary metal oxide semiconductor (CMOS) image sensor (CIS) may have a cover glass on a light receiving surface side of a sensor chip. The cover glass is arranged at a distance from the light receiving surface of the sensor chip, and a resin is provided on a side surface of the cover glass.

### CITATION LIST

### Patent Document

Patent Document 1: Japanese Patent Application Laid-Open No. 2009-188191

### SUMMARY OF THE INVENTION

### Problems to be Solved by the Invention

A resin has a higher coefficient of thermal expansion (CTE) than glass. Therefore, thermal stress is generated at an interface between the cover glass and the resin. Furthermore, an internal pressure of a space between the sensor chip and the cover glass changes, and warpage may occur in the cover glass. Such thermal stress or warpage of the cover glass causes cracking or peeling of the cover glass.

In this regard, a solid-state imaging device capable of suppressing cracking or peeling of a cover glass is provided.

### Solutions to Problems

A solid-state imaging device according to one aspect of the present disclosure includes: a photoelectric conversion element that has a light receiving surface; a glass member that is provided above the light receiving surface; and a first resin member that covers a side surface of the photoelectric conversion element and a side surface of the glass member. An area of the photoelectric conversion element is 59 mm² or more in a plan view viewed from a first direction substantially perpendicular to the light receiving surface, the glass member protrudes from the photoelectric conversion element by a first width of 15% to 93% of a width of the first resin member in a second direction substantially parallel to the light receiving surface, and a thickness of the glass member is 40% or more of a thickness of the first resin member in the first direction.

The side surface of the glass member is covered with the first resin member.

The thickness of the glass member is equal to or less than the thickness of the first resin member.

The solid-state imaging device further includes: a second resin member that is provided between the glass member and the photoelectric conversion element at an outer edge of the photoelectric conversion element and forms a space between the glass member and the photoelectric conversion element.

The first and second resin members are provided on an entire outer edge of the photoelectric conversion element and seal the space.

The glass member protrudes from the photoelectric conversion element by the first width in the second direction over an entire outer edge of the photoelectric conversion element.

The thickness of the glass member is 40% or more of the thickness of the first resin member in the first direction over an entire outer edge of the photoelectric conversion element.

The solid-state imaging device further includes: a wiring substrate on which the photoelectric conversion element is mounted on a first surface. The first resin member is provided on a surface of the wiring substrate so as to surround a periphery of the photoelectric conversion element.

The solid-state imaging device further includes: a metal bump that is provided on a second surface of the wiring substrate opposite to the first surface.

The solid-state imaging device further includes: a metal wire that electrically connects a wiring of the wiring substrate and the photoelectric conversion element. The metal wire is covered with the first resin member.

### BRIEF DESCRIPTION OF DRAWINGS

FIG. 1 is a cross-sectional view illustrating a configuration example of a solid-state imaging device according to a first embodiment.

FIG. 2 is a schematic diagram illustrating a configuration example of a semiconductor chip.

FIG. 3 is a block diagram illustrating an example of a circuit configuration of the semiconductor chip.

FIG. 4 is an equivalent circuit diagram illustrating a configuration example of a pixel.

FIG. 5 is a cross-sectional view illustrating a configuration example of an end portion of the solid-state imaging device according to the first embodiment.

FIG. 6 is a plan view illustrating an arrangement example of the semiconductor chip, a mold resin, and a cover glass.

FIG. 7 is a graph illustrating a state of occurrence of cracking of the cover glass or peeling of a mold resin 17 with respect to a chip size of the semiconductor chip.

FIG. 8 is a graph illustrating a state of occurrence of cracking at an end portion of the cover glass when a protrusion width and a thickness of the cover glass are changed.

FIG. 9 is a graph illustrating interfacial stress between the mold resin and the cover glass.

FIG. 10 is a graph illustrating interfacial stress between the mold resin and the cover glass.

FIG. 11 is a schematic diagram illustrating an example of a method of manufacturing the solid-state imaging device according to the present embodiment.

FIG. 12 is a schematic diagram illustrating an example of a method of manufacturing the solid-state imaging device, following FIG. 11.

FIG. 13 is a schematic diagram illustrating an example of a method of manufacturing the solid-state imaging device, following FIG. 12.

FIG. 14 is a schematic diagram illustrating an example of a method of manufacturing the solid-state imaging device, following FIG. 13.

FIG. 15 is a schematic diagram illustrating an example of a method of manufacturing the solid-state imaging device, following FIG. 14.

FIG. 16 is a schematic diagram illustrating an example of a method of manufacturing the solid-state imaging device, following FIG. 15.

FIG. 17 is a schematic diagram illustrating an example of a method of manufacturing the solid-state imaging device, following FIG. 16.

FIG. 18 is a schematic diagram illustrating an example of a method of manufacturing the solid-state imaging device, following FIG. 17.

FIG. 19 is a schematic diagram illustrating an example of a method of manufacturing the solid-state imaging device according to a second embodiment.

FIG. 20 is a cross-sectional view illustrating a configuration example of the solid-state imaging device according to the second embodiment.

FIG. 21 is a block diagram illustrating a schematic configuration example of a vehicle control system.

FIG. 22 is a diagram illustrating an example of an installation position of an imaging section.

### MODE FOR CARRYING OUT THE INVENTION

Hereinafter, specific embodiments according to the present technology will be described in detail with reference to the drawings. The drawings are schematic or conceptual, and the ratio of each part and the like are not necessarily the same as actual ones. In the specification and the drawings, similar elements to those described above concerning the previously described drawings are denoted by the same reference signs, and detailed descriptions thereof are appropriately omitted.

### First Embodiment

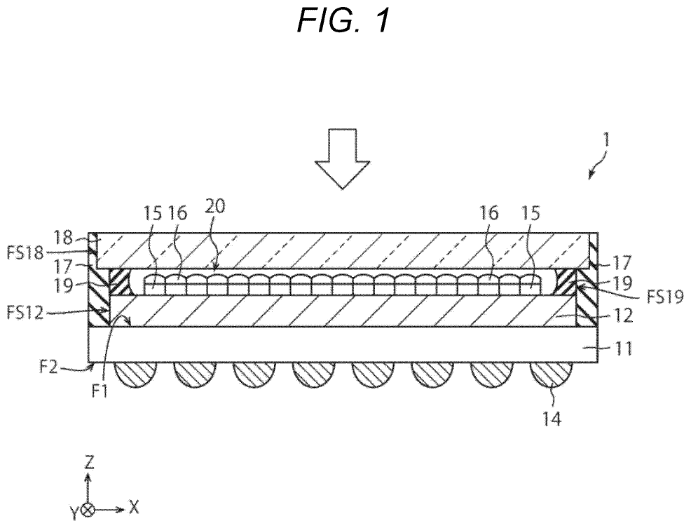

FIG. 1 is a cross-sectional view illustrating a configuration example of a solid-state imaging device 1 according to a first embodiment. The solid-state imaging device 1 includes a wiring substrate 11, a semiconductor chip 12, a metal bump 14, a color filter 15, an on-chip lens 16, a mold resin 17, a cover glass 18, and a seal member 19. The solid-state imaging device 1 is, for example, a semiconductor package of a CIS that converts incident light from a direction indicated by an arrow in the drawing into an electric signal.

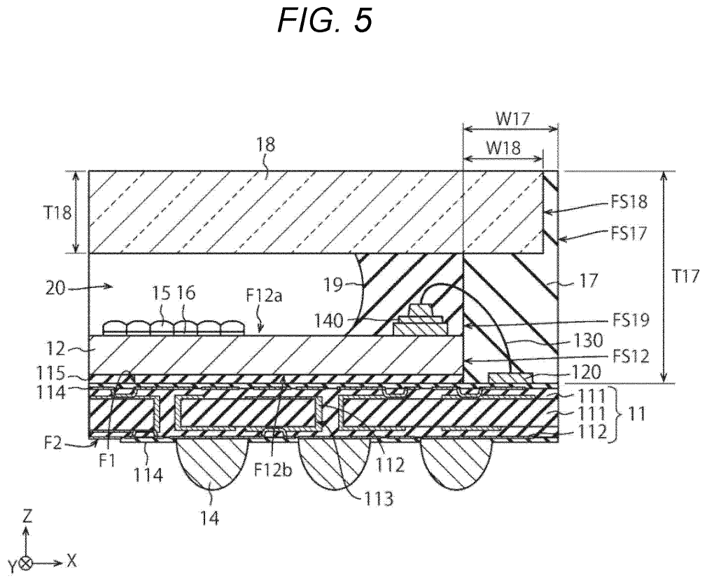

The wiring substrate 11 has a multilayer wiring structure (see FIG. 5) in which an insulating layer and a wiring layer are laminated. The semiconductor chip 12 is mounted on a first surface F1 of the wiring substrate 11. A plurality of metal bumps 14 for electrically connecting with an external substrate (not illustrated) is provided on a second surface F2 of the wiring substrate 11 on the opposite side of the first surface F1. The metal bump 14 is connected to the wiring layer, and is electrically connected to the semiconductor chip 12 via the wiring layer or a metal wire. For the metal bump 14, for example, a conductive material such as solder is used.

The semiconductor chip 12 as a photoelectric conversion element has a light receiving surface that receives incident light. A red (R), green (G), or blue (B) color filter 15 and an on-chip lens 16 are provided on the light receiving surface of the semiconductor chip 12.

The cover glass 18 is provided above the semiconductor chip 12 and protects the light receiving surface of the semiconductor chip 12. For the cover glass 18, for example, a transparent material such as glass, silicon nitride, sapphire, or resin is used. The cover glass 18 allows incident light to pass through the light receiving surface of the semiconductor chip 12.

A seal member 19 as a second resin member is provided between the cover glass 18 and the semiconductor chip 12 along the outer edge of the semiconductor chip 12. The seal member 19 forms a space 20 between the cover glass 18 and the light receiving surface of the semiconductor chip 12. For the seal member 19, for example, a resin material such as an acrylic resin, a styrene resin, or an epoxy resin is used.

The mold resin 17 as a first resin member is provided on the side portion of the solid-state imaging device, and covers a side surface FS12 of the semiconductor chip 12, a side surface FS18 of the glass member 18, and a side surface FS19 of the seal member 19. Furthermore, the mold resin 17 is provided on the first surface F1 over the outer edge of the wiring substrate 11. For example, resin is used for the mold resin 17.

The space 20 is sealed by the semiconductor chip 12, the cover glass 18, and the seal member 19.

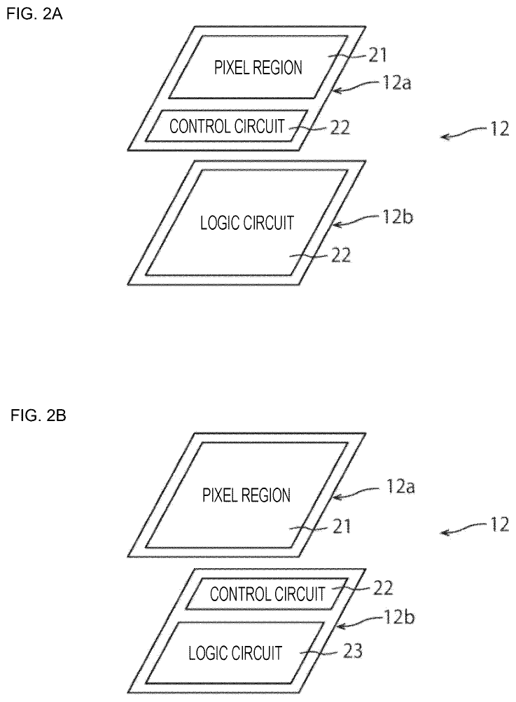

FIG. 2 is a schematic diagram illustrating a configuration example of the semiconductor chip 12. The semiconductor chip 12 is, for example, a stacked chip of an upper substrate 12a and a lower substrate 12b. For example, as illustrated in FIG. 2A, the upper substrate 12a is provided with a pixel region 21 in which pixels that perform photoelectric conversion are two-dimensionally arranged and a control circuit 22 that controls the pixels, and the lower substrate 12b is provided with a logic circuit 23 such as a signal processing circuit that processes pixel signals output from the pixels. Alternatively, as illustrated in FIG. 2B, only the pixel region 21 may be provided on the upper substrate 12a, and the control circuit 22 and the logic circuit 23 may be provided on the lower substrate 12b.

As described above, in the semiconductor chip 12, the logic circuit 23 or one or both of the control circuit 22 and the logic circuit 23 may be provided on the lower substrate 12b different from the upper substrate 12a of the pixel region 21.

Therefore, the size of the solid-state imaging device 1 can be reduced as compared with a case where the pixel region 21, the control circuit 22, and the logic circuit 23 are arranged in a planar direction on one substrate.

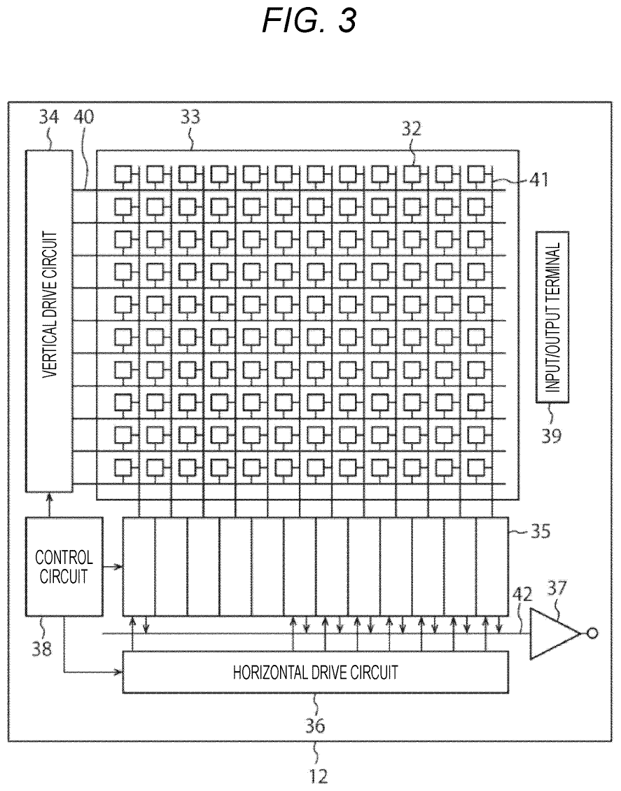

FIG. 3 is a block diagram illustrating an example of a circuit configuration of the semiconductor chip 12. The semiconductor chip 12 includes a pixel region 21 in which pixels 32 are arranged in a two-dimensional array, a vertical drive circuit 34, a column signal processing circuit 35, a horizontal drive circuit 36, an output circuit 37, a control circuit 38, an input/output terminal 39, and the like.

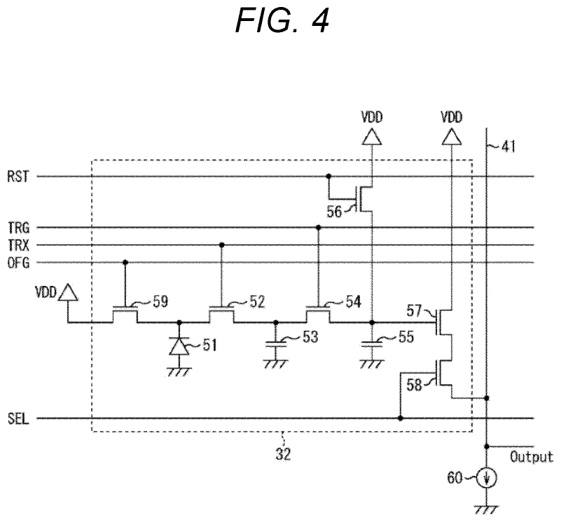

The pixel 32 includes a photodiode as a photoelectric conversion element and a plurality of pixel transistors. An example of a circuit configuration of the pixel 32 will be described later with reference to FIG. 4.

The control circuit 38 receives an input clock and data giving a command of an operation mode and the like, and outputs data of internal information and the like of the semiconductor chip 12. That is, the control circuit 38 generates a clock signal and a control signal which serve as a reference for operations of the vertical drive circuit 34, the column signal processing circuit 35, the horizontal drive circuit 36 and the like on the basis of a vertical synchronization signal, a horizontal synchronization signal, and a master clock. The control circuit 38 outputs the generated clock signal and control signal to the vertical drive circuit 34, the column signal processing circuit 35, the horizontal drive circuit 36, and the like.

The vertical drive circuit 34 includes, for example, a shift register, selects predetermined pixel drive wiring 40, supplies a pulse for driving the pixels 32 to the selected pixel drive wiring 40, and drives the pixels 32 in units of rows. That is, the vertical drive circuit 34 sequentially selects to scan each pixel 32 in the pixel region 21 in a vertical direction in units of row, and supplies a pixel signal based on a signal charge generated according to a received light amount by a photoelectric conversion unit of each pixel 32 to the column signal processing circuit 35 via a vertical signal line 41.

The column signal processing circuit 35 is arranged for each column of the pixels 32 and performs signal processing such as noise removal on the signals output from the pixels 32 of one row for each pixel column. For example, the column signal processing circuit 35 performs signal processing such as correlated double sampling (CDS) for removing a pixel-specific fixed pattern noise and analog-to-digital (AD) conversion.

The horizontal drive circuit 36 includes, for example, a shift register, selects each of the column signal processing circuits 35 in turn by sequentially outputting horizontal scanning pulses, and allows each of the column signal processing circuits 35 to output the pixel signal to a horizontal signal line 42.

The output circuit 37 performs signal processing on the signals sequentially supplied from each of the column signal processing circuits 35 via the horizontal signal line 42 to output. For example, there is a case where the output circuit 37 performs only buffering, or a case where the output circuit 37 performs black level adjustment, column variation correction, various types of digital signal processing, and the like. An input/output terminal 39 exchanges signals with the outside.

The semiconductor chip 12 configured as described above is a CIS called a column AD method in which the column signal processing circuits 35 that perform CDS processing and AD conversion processing are arranged for each pixel column.

FIG. 4 is an equivalent circuit diagram illustrating a configuration example of the pixel 32. The pixel 32 illustrates a configuration that implements an electronic global shutter function.

The pixel 32 includes a photodiode 51 as a photoelectric conversion element, a first transfer transistor 52, a memory unit (MEM) 53, a second transfer transistor 54, a floating diffusion region (FD) 55, a reset transistor 56, an amplifier transistor 57, a selection transistor 58, and a discharge transistor 59.

The photodiode 51 is a photoelectric conversion unit that generates and accumulates charge (signal charge) corresponding to the received light amount. An anode terminal of the photodiode 51 is grounded, and a cathode terminal thereof is connected to the memory unit 53 via the first transfer transistor 52. Furthermore, the cathode terminal of the photodiode 51 is also connected to the discharge transistor 59 for discharging an unnecessary charge.

When turned on by a transfer signal TRX, the first transfer transistor 52 reads the charge generated by the photodiode 51 to transfer to the memory unit 53. The memory unit 53 is a charge holding unit that temporarily holds the charge until the charge is transferred to the FD 55.

When turned on by a transfer signal TRG, the second transfer transistor 54 reads the charge held in the memory unit 53 to transfer to the FD 55.

The FD 55 is a charge holding unit that holds the charges read from the memory unit 53 in order to read the charges as signals. When turned on by a reset signal RST, the reset transistor 56 resets the potential of the FD 55 by discharging the charges accumulated in the FD 55 to a constant voltage source VDD.

The amplifier transistor 57 outputs the pixel signal corresponding to the potential of the FD 55. That is, the amplifier transistor 57 constitutes a source follower circuit with a load MOS 60 as a constant current source, and a pixel signal indicating a level according to the charge accumulated in the FD 55 is output from the amplifier transistor 57 to the column signal processing circuit 35 (FIG. 3) via the selection transistor 58. The load MOS 60 is arranged, for example, in the column signal processing circuit 35.

The selection transistor 58 is turned on when the pixel 32 is selected by a selection signal SEL, and outputs the pixel signal of the pixel 32 to the column signal processing circuit 35 via the vertical signal line 41.

When turned on by a discharge signal OFG, the discharge transistor 59 discharges the unnecessary charge accumulated in the photodiode 51 to the constant voltage source VDD.

The transfer signals TRX and TRG, the reset signal RST, the discharge signal OFG, and the selection signal SEL are supplied from the vertical drive circuit 34 via the pixel drive wiring 40.

The operation of the pixel 32 will be briefly described.

First, before exposure is started, the discharge transistor 59 is turned on when the discharge signal OFG at a high level is supplied to the discharge transistor 59, the charge accumulated in the photodiode 51 is discharged to the constant voltage source VDD, and the photodiodes 51 of all the pixels are reset.

After the photodiodes 51 are reset, when the discharge transistor 59 is turned off by a low-level discharge signal OFG, exposure is started in all the pixels of the pixel region 21.

When a predetermined exposure time determined in advance elapses, the first transfer transistor 52 is turned on by the transfer signal TRX, and the charge accumulated in the photodiode 51 is transferred to the memory unit 53 in all the pixels of the pixel region 21.

After the first transfer transistor 52 is turned off, the charge held in the memory unit 53 of each pixel 32 is sequentially read to the column signal processing circuit 35 in units of rows. In the read operation, the second transfer transistor 54 of the pixel 32 of a read row is turned on by the transfer signal TRG, and the charge held in the memory unit 53 is transferred to the FD 55. Then, when the selection transistor 58 is turned on by the selection signal SEL, a signal indicating a level corresponding to the charge accumulated in the FD 55 is output from the amplifier transistor 57 to the column signal processing circuit 35 via the selection transistor 58.

As described above, in the pixel 32, the exposure time is set to be the same in all the pixels of the pixel region 21, and after the exposure is finished, the charge is temporarily held in the memory unit 53, and a global shutter operation (imaging) of sequentially reading the charge from the memory unit 53 row by row is possible.

Note that the circuit configuration of the pixel 32 is not limited to the configuration illustrated in FIG. 4, and for example, a circuit configuration that does not include the memory unit 53 and performs an operation by a so-called rolling shutter system can be adopted.

Furthermore, the pixel 32 can have a shared pixel structure in which some pixel transistors are shared by a plurality of pixels. For example, a configuration in which the first transfer transistor 52, the memory unit 53, and the second transfer transistor 54 are included in units of pixels 32, and the FD 55, the reset transistor 56, the amplifier transistor 57, and the selection transistor 58 are shared by a plurality of pixels and the like such as four pixels may be adopted.

FIG. 5 is a cross-sectional view illustrating a configuration example of an end portion of the solid-state imaging device 1 according to the first embodiment. The wiring substrate 11 has a multilayer wiring structure in which an insulating layer 111 and a wiring layer 112 are laminated. A solder resist 114 is provided on the first surface F1 and the second surface F2 of the wiring substrate 11. On the first surface F1 side, the semiconductor chip 12 is bonded onto the solder resist 114 by an adhesive layer 115. Furthermore, on the first surface F1, a pad 120 is provided in a region where the solder resist 114 is not provided. The pad 120 is connected to the wiring layer 112. For the pad 120, for example, a conductive material such as copper is used. On the other hand, on the second surface F2 side, the metal bump 14 is provided in a region where the solder resist 114 is not provided. The metal bump 14 is connected to the wiring layer 112. The wiring substrate 11 is provided with a through via 113. The through via 113 penetrates the insulating layer 111 of the wiring substrate 11 between the first surface F1 and the second surface F2. The wiring layer 112 is provided on an inner wall surface of the through via 113, and the insulating layer 111 is embedded inside the wiring layer 112. Therefore, the wiring layer 112 on the first surface F1 side is electrically connected to the wiring layer 112 on the second surface F2 side via the through via 113. For the wiring layer 112, for example, a conductive material such as copper is used.

The color filter 15 and the on-chip lens 16 are provided on a light receiving surface F12a of the semiconductor chip 12. Furthermore, a pad 140 is provided on the light receiving surface F12a of the semiconductor chip 12, and a metal wire 130 is connected thereto. The metal wire 130 electrically connects the pad 140 and the pad 120. For the metal wire 130, for example, a conductive material such as a gold wire is used. For the pad 140, for example, a conductive material such as copper is used.

The seal member 19 is provided between the semiconductor chip 12 and the cover glass 18 along the outer edge of the semiconductor chip 12. The seal member 19 covers the bonding portion of the pad 140 and the metal wire 130, and protects the bonding portion. Furthermore, the seal member 19 is provided over the entire outer edge of the semiconductor chip 12, and seals a space between the semiconductor chip 12 and the cover glass 18.

The cover glass 18 is supported by the seal member 19 and is fixed above the light receiving surface F12a of the semiconductor chip 12.

The mold resin 17 is provided along the outer edges of the semiconductor chip 12, the cover glass 18, and the wiring layer 112 so as to cover the side surface FS12 of the semiconductor chip 12, the side surface FS17 of the cover glass 18, and the side surface FS19 of the seal member 19. Therefore, the mold resin 17 protects the end portions of the cover glass 18 and the semiconductor chip 12. Furthermore, the mold resin 17 covers the bonding portion of the pad 120 and the metal wire 130, and protects the bonding portion. The mold resin 17 is provided over the entire outer edge of the semiconductor chip 12, and seals the space between the semiconductor chip 12 and the cover glass 18.

Here, the end portion of the cover glass 18 protrudes in an X direction and/or a Y direction substantially parallel to the light receiving surface F12a of the semiconductor chip 12. A protrusion width W18 of the cover glass 18 is 15% to 93% of a width W17 of the mold resin 17 in the X or Y direction. The protrusion width W18 of the cover glass 18 is a distance in the X or Y direction from the side surface FS12 of the semiconductor chip 12 (an interface between the side surface FS12 of the semiconductor chip 12 and the mold resin 17) to the side surface FS18 of the cover glass 18. The width W17 of the mold resin 17 is a distance in the X or Y direction from the side surface FS12 of the semiconductor chip 12 (the interface between the side surface FS12 of the semiconductor chip 12 and the mold resin 17) to the side surface FS17 of the mold resin 17.

Furthermore, the thickness T18 of the cover glass 18 is 40% or more of the thickness T17 of the mold resin 17 in a Z direction. Furthermore, the thickness T18 of the cover glass 18 is equal to or less than the thickness T17 of the mold resin 17 in the Z direction. The thickness T18 of the cover glass 18 is a distance in the Z direction from a bottom surface of the cover glass 18 (an interface between the bottom surface of the cover glass 18 and the space 20, the seal member 19, or the mold resin 17) to the upper surface of the cover glass 18. The thickness T17 of mold resin 17 is a distance in the Z direction from the bottom surface of the mold resin 17 (an interface between the bottom surface of the mold resin 17 and the first surface F1 of the wiring substrate 11) to the upper surface of the mold resin 17. Note that the protrusion width W18 and the thickness T18 of the cover glass 18 will be described later with reference to FIG. 7.

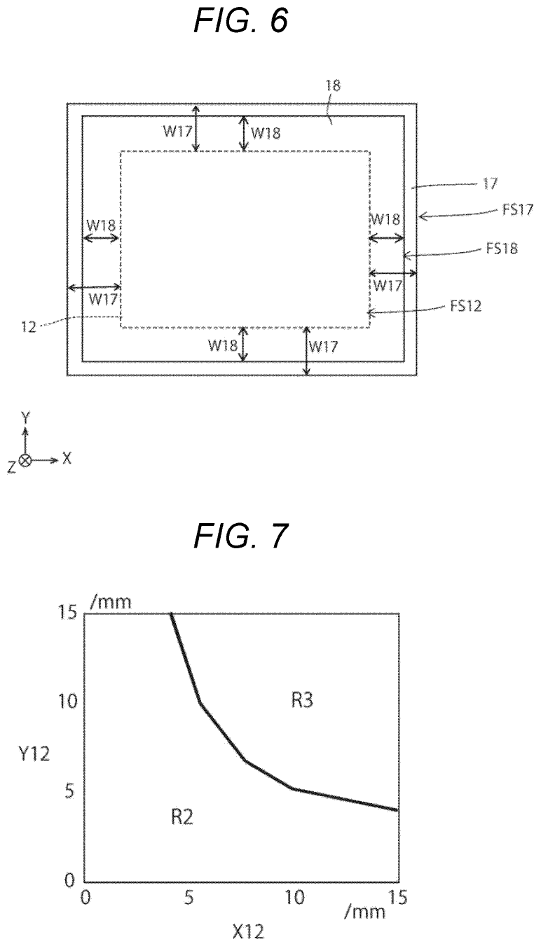

FIG. 6 is a plan view illustrating an arrangement example of the semiconductor chip 12, the mold resin 17, and the cover glass 18. In the present embodiment, the cover glass 18 protrudes over the entire outer edge of the light receiving surface F12a in the X direction and the Y direction substantially parallel to the light receiving surface F12a of the semiconductor chip 12. However, as described above, the protrusion width W18 is 15% to 93% of the width W17 of the mold resin 17 in the X or Y direction. Therefore, the mold resin 17 is provided over the entire outer edge of the cover glass 18 and the semiconductor chip 12, so as to surround the periphery of the semiconductor chip 12. Furthermore, the seal member 19 is also provided over the entire outer edges of the cover glass 18 and the semiconductor chip 12. Thus, the seal member 19 and the mold resin 17 are provided over the entire outer edge of the space 20, and seal the space 20.

FIG. 7 is a graph illustrating a state of occurrence of cracking of the cover glass 18 or peeling of the mold resin 17 with respect to the chip size of the semiconductor chip 12. A vertical axis represents the length of the semiconductor chip 12 in the Y direction in plan view as viewed from the Z direction. A horizontal axis represents the length of the semiconductor chip 12 in the X direction in plan view as viewed from the Z direction.

A region R2 is a region where cracking of the cover glass 18 or peeling of the mold resin 17 does not occur. A region R3 is a region where cracking of the cover glass 18 or peeling of the mold resin 17 occurs. Referring to FIG. 7, it can be seen that the chip size of the semiconductor chip 12 (the area of the light receiving surface F12a) is related to the cracking of the cover glass 18 in the plan view seen from the Z direction. When the chip size of the semiconductor chip 12 (the area of the light receiving surface F12a) is about 59 mm² or more, the cracking of the cover glass 18 or the peeling of the mold resin 17 is likely to occur. When the chip size of the semiconductor chip 12 (the area of the light receiving surface F12a) is less than about 59 mm², the cracking of the cover glass 18 or the peeling of the mold resin 17 hardly occurs. As described above, it has been seen that when the chip size of the semiconductor chip 12 (the area of the light receiving surface F12a) exceeds about 59 mm², cracking is likely to occur at the end portion of the cover glass 18, or the mold resin 17 is easily peeled off from the cover glass 18.

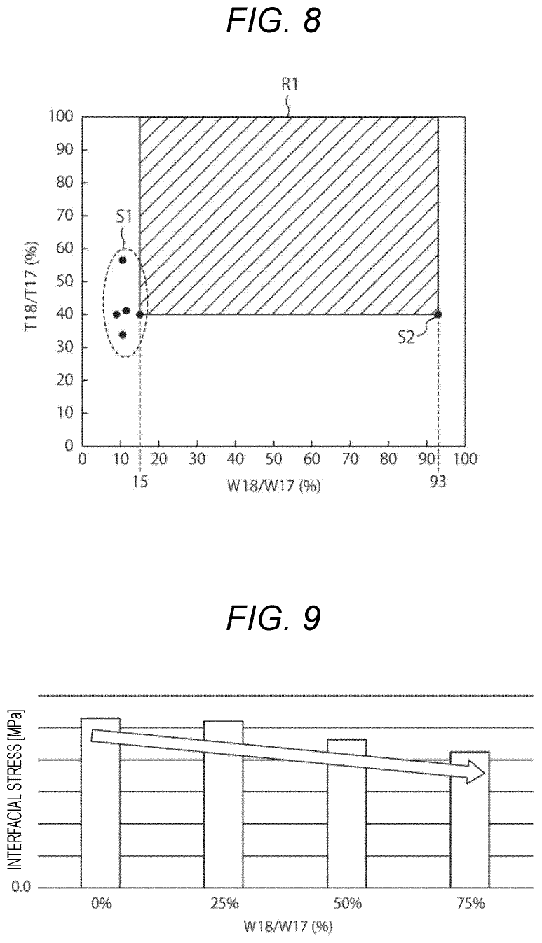

FIG. 8 is a graph illustrating a state of occurrence of cracking at the end portion of the cover glass 18 when the protrusion width W18 and the thickness T18 of the cover glass 18 are changed. A vertical axis represents the ratio (%) of the thickness T18 of the cover glass 18 to the thickness T17 of the mold resin 17. A horizontal axis represents the ratio (%) of the protrusion width W18 of the cover glass 18 to the width W17 of the mold resin 17. Note that samples S1 and S2 include both a ball grid array (BGA) using the mold resin 17 and a BGA using potting resin.

When the chip size of the semiconductor chip 12 is set to about 59 mm² and the package of the solid-state imaging device 1 is actually observed, in the sample S1, the protrusion width W18 of the cover glass 18 is less than 15% of W17, and thus the cracking of the cover glass 18 or the peeling of the mold resin 17 occurs. In the sample S2, the protrusion width W18 of the cover glass 18 exceeds 93% of W17, and thus the outer periphery of the cover glass 18 cannot be covered with the mold resin 17 due to design such as glass mounting accuracy, glass size tolerance, and package outer shape size tolerance. Alternatively, when the package is singulated, the mold resin 17 may be cracked or peeled off. In some of the sample S1 and the sample S2, the thickness T18 of the cover glass 18 exceeds 40% of T17, and thus the cracking of the cover glass 18 or the peeling of the mold resin 17 occurs.

On the other hand, in a case where the protrusion width W18 of the cover glass 18 is 15% to 93% of W17 and the thickness T18 of the cover glass 18 is 40% to 100% of T17, the cracking of the cover glass 18 or the peeling of the mold resin 17 hardly occurs. That is, under the condition within the range of the region R1 in FIG. 8, the side surface stress of the cover glass 18 can be reduced, and the cracking of the cover glass 18 or the peeling of the mold resin 17 hardly occurs.

The reason why the cracking of the cover glass 18 or the peeling of the mold resin 17 is suppressed as described above is as follows. That is, by increasing the thickness of the cover glass 18, the warpage of the cover glass 18 with respect to the change in the internal pressure of the space 20 is suppressed. When the warpage of the cover glass 18 is suppressed, it is possible to suppress concentration of stress between the end portion of the cover glass 18 and the mold resin 17. Furthermore, by protruding the end portion of the cover glass 18 toward the mold resin 17, it is possible to suppress concentration of thermal stress due to the difference in thermal expansion coefficient between the cover glass 18 and the mold resin 17 on the interface between the side surface FS18 of the cover glass 18 and the mold resin 17. Therefore, the cracking of the cover glass 18 or the peeling of the mold resin 17 can be suppressed.

As illustrated in FIG. 8, it has been seen that the protrusion width W18 and the thickness T18 of the cover glass 18 are correlated with the width W17 and the thickness T17 of the mold resin 17. In the configuration within the range of the region R1, the stress concentration on the end portion of the cover glass 18 is reduced, and the cracking thereof can be suppressed.

In a case where the chip size of the semiconductor chip 12 is less than about 59 mm², the chip size falls within the region R2 of FIG. 7, so that cracking of the cover glass 18 and the peeling of the mold resin 17 hardly occur. Thus, even if the protrusion width W18 and the thickness T18 of the cover glass 18 are out of the range of the region R1 in FIG. 8, there is no problem.

However, in a case where the chip size of the semiconductor chip 12 is about 59 mm² or more, the chip size falls within the region R3 of FIG. 7, so that the cracking of the cover glass 18 and the peeling of the mold resin 17 are likely to occur. Therefore, the protrusion width W18 and the thickness T18 of the cover glass 18 are preferably within the range of the region R1 in FIG. 8. Therefore, the cracking of the cover glass 18 and the peeling of the mold resin 17 can be suppressed.

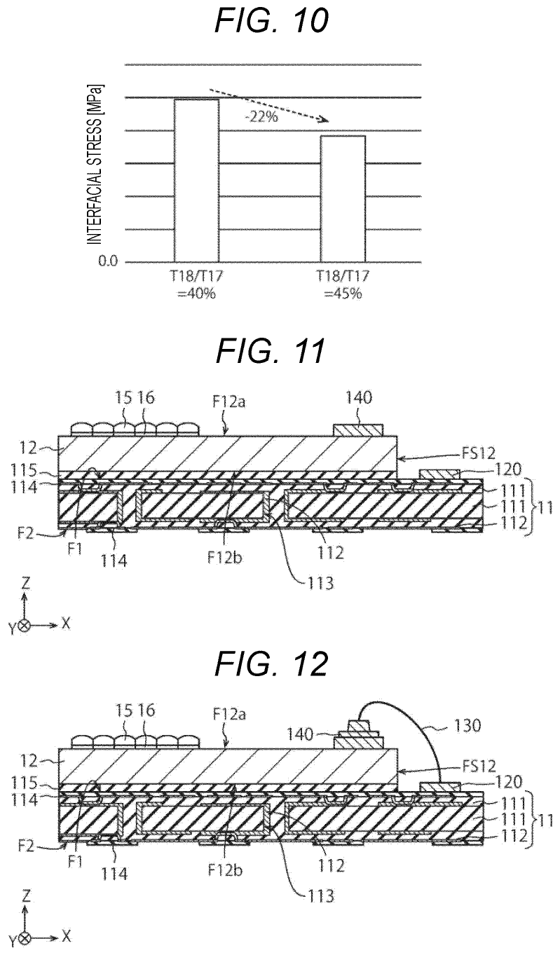

FIGS. 9 and 10 are graphs illustrating interfacial stress between the mold resin 17 and the cover glass 18.

The vertical axis of the graph of FIG. 9 represents the stress at the interface between the mold resin 17 and the cover glass 18. The horizontal axis of the graph of FIG. 9 represents the ratio of the protrusion width W18 of the cover glass 18 to the width W17 of the mold resin 17. The interfacial stress between the mold resin 17 and the cover glass 18 increases when the difference between the thermal expansion coefficient of the mold resin 17 and the thermal expansion coefficient of the cover glass 18 is large. When the interfacial stress between the mold resin 17 and the cover glass 18 is large, the cracking of the cover glass 18 are caused. For example, the interfacial stress between the mold resin 17 and the cover glass 18 increases due to a reflow process (for example, 260° C.) after formation of the mold resin 17, a thermal cycle test (for example, −55° C.), or the like, and the cover glass 18 may be broken or the mold resin 17 may be peeled off from the cover glass 18.

According to the graph of FIG. 9, it can be seen that the interfacial stress between the mold resin 17 and the cover glass 18 decreases by fixing the width W17 of the mold resin 17 and increasing the protrusion width W18 of the cover glass 18. That is, it is considered that by increasing the protrusion width W18 of the cover glass 18, the stress applied to the cover glass 18 is relaxed, and the cracking of the cover glass 18 or the peeling of the mold resin 17 is reduced.

The vertical axis of the graph of FIG. 10 is the same as the vertical axis of FIG. 9. The horizontal axis of the graph of FIG. 10 represents the ratio of the thickness T18 of the cover glass 18 to the thickness T17 of the mold resin 17.

According to the graph of FIG. 10, it can be seen that the interfacial stress between the mold resin 17 and the cover glass 18 decreases by fixing the thickness T17 of the mold resin 17 and increasing the thickness T18 of the cover glass 18. That is, it is considered that by increasing the thickness T18 of the cover glass 18, the stress applied to the cover glass 18 is relaxed, and the cracking of the cover glass 18 or the peeling of the mold resin 17 is reduced.

From the above, according to the present embodiment, a condition that the cracking of the cover glass 18 or the peeling off of the mold resin 17 does not occur is preferably that in a case where the chip size of the semiconductor chip 12 is about 59 mm² or more (in the region R3 in FIG. 7), the protrusion width W18 of the cover glass 18 is 15% to 93% of W17, and the thickness T18 of the cover glass 18 is 40% to 100% of T17 (in the region R1 in FIG. 8). Under such a condition, it has been seen that the cracking of the cover glass 18 or the peeling of the mold resin 17 can be effectively suppressed.

Furthermore, by setting the protrusion width W18 of the cover glass 18 to 15% to 93% of the width W17 of the mold resin 17, the mold resin 17 covers the side surface FS18 of the cover glass 18 as illustrated in FIG. 5. Therefore, it is possible to suppress light from entering from the side surface FS18 of the cover glass 18 and to suppress flare due to diffuse reflection of light.

### Method of Manufacturing Solid-State Imaging Device 1

FIGS. 11 to 18 are schematic diagrams illustrating an example of a method of manufacturing the solid-state imaging device 1 according to the present embodiment. FIGS. 11 to 18 illustrate the end portion of the solid-state imaging device 1.

The semiconductor chip 12 is formed by singulating a semiconductor wafer processed in a pre-process of a semiconductor control process in a dicing process.

Next, as illustrated in FIG. 11, the semiconductor chip 12 is bonded onto the first surface F1 of the wiring substrate 11 with the adhesive layer 115. For example, a die attach film (DAF) or the like is used for the adhesive layer 115. The adhesive layer 115 is attached in advance to the back surface F12b side of the semiconductor chip 12. By placing the semiconductor chip 12 on the first surface F1 of the wiring substrate 11 and performing heat treatment, the semiconductor chip 12 is bonded onto the first surface F1 of the wiring substrate 11 by the adhesive layer 115. Note that the adhesive layer 115 is a liquid adhesive, and the semiconductor chip 12 may be fixed onto the wiring substrate 11 through a curing process with an outer line or the like.

Next, after the semiconductor chip 12 and the wiring substrate 11 are plasma-cleaned, as illustrated in FIG. 12, the pad 120 provided on the first surface F1 of the wiring substrate 11 and the pad 140 provided on the light receiving surface F12a of the semiconductor chip 12 are connected by the metal wire 130 by using a wire bonding technique. Therefore, the semiconductor chip 12 is electrically connected to any of the wiring layers 112 of the wiring substrate 11.

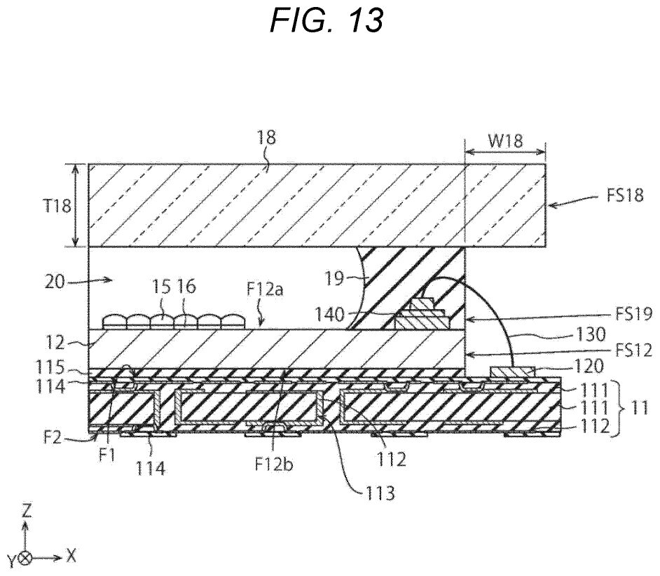

Next, as illustrated in FIG. 13, the seal member 19 is supplied to the outer edge of the semiconductor chip 12, and the cover glass 18 is placed on the seal member 19. The seal member 19 is, for example, a thermoplastic resin, covers the pad 140 and the connection portion between the metal wire 130 and the pad 140 by heat treatment, and fixes the cover glass 18 above the light receiving surface F12a of the semiconductor chip 12. Alternatively, the seal member 19 is a liquid resin, and is supplied to the pad 140 and the connection portion between the metal wire 130 and the pad 140. After the cover glass 18 is placed on the seal member 19, the seal member 19 is solidified by being cured with ultraviolet rays or the like. Therefore, the seal member 19 covers the pad 140 and the connection portion between the metal wire 130 and the pad 140, and fixes the cover glass 18 above the light receiving surface F12a of the semiconductor chip 12.

The seal member 19 fixes the cover glass 18 above the light receiving surface F12a of the semiconductor chip 12 with the space 20 therebetween. Therefore, the cover glass 18 does not come into contact with the on-chip lens 16 of the light receiving surface F12a of the semiconductor chip 12, and can transmit the incident light to the light receiving surface F12a.

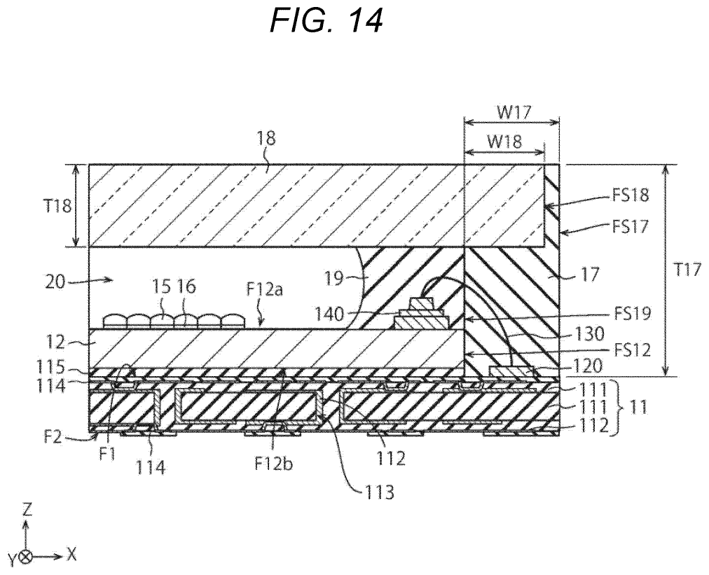

Next, as illustrated in FIG. 14, the mold resin 17 is supplied onto the side surface FS18 of the cover glass 18, the side surface FS19 of the seal member 19, the side surface FS12 of the semiconductor chip 12, and the first surface F1 of the wiring substrate 11 by using a mold molding technique or the like. Therefore, the mold resin 17 seals the pad 120, the metal wire 130, and the connection portion therebetween.

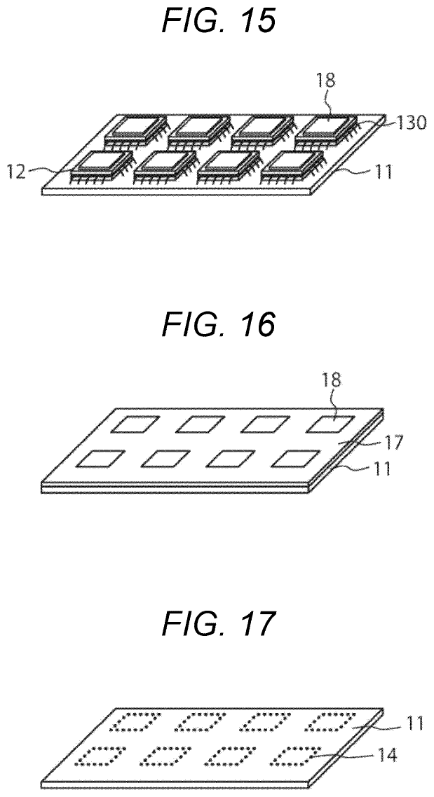

For example, FIG. 15 illustrates the wiring substrate 11 before resin sealing on which a plurality of semiconductor chips 12 is mounted. FIG. 16 illustrates the wiring substrate 11 after resin sealing. In this manner, the mold resin 17 is not supplied to the surface of the cover glass 18, and fills a space between adjacent semiconductor chips 12 or a space between adjacent cover glasses 18. Therefore, the metal wire 130 and the like are protected by the mold resin 17 without attaching the mold resin 17 to the surface of the cover glass 18. The mold resin 17 is cured in a curing process.

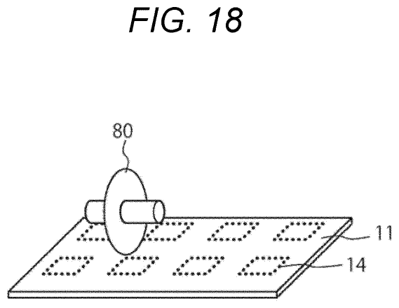

Next, as illustrated in FIG. 17, the metal bump 14 is formed on the second surface F2 side of the wiring substrate 11. Next, as illustrated in FIG. 18, the wiring substrate 11 is cut from the second surface F2 side of the wiring substrate 11 by using a dicing blade 80. Therefore, each semiconductor chip 12 is singulated, and the package of the solid-state imaging device 1 illustrated in FIG. 1 or 5 is completed.

### Second Embodiment

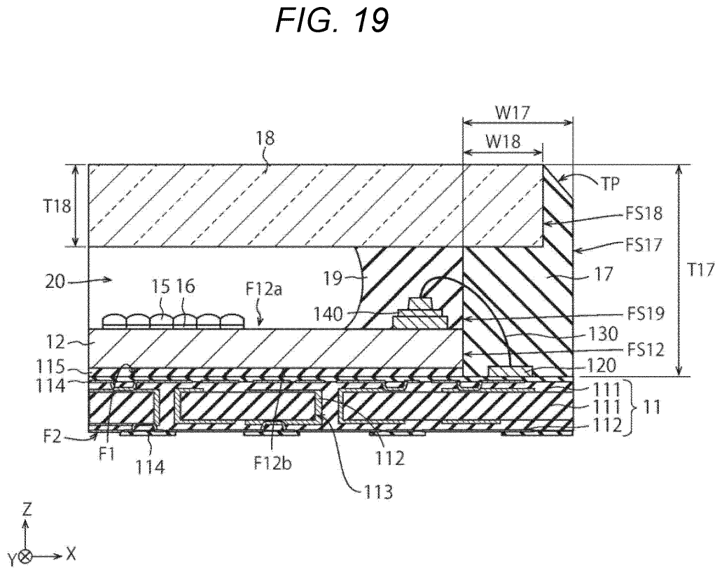

FIG. 19 is a schematic diagram illustrating an example of a method of manufacturing the solid-state imaging device 1 according to a second embodiment. In the manufacturing method of the first embodiment, the semiconductor chip 12 and the like are sealed with the mold resin 17 by using a die molding technique. On the other hand, in the second embodiment, in the processes illustrated in FIGS. 15 and 16, the resin 17 is formed by a potting method. That is, the liquid resin is supplied (potted) between adjacent semiconductor chips 12 or between adjacent cover glasses 18 on the wiring substrate 11, and cured by ultraviolet rays or the like. Therefore, the resin 17 is embedded between the adjacent semiconductor chips 12 or between the adjacent cover glasses 18. That is, a structure equivalent to the structure illustrated in FIGS. 14 and 16 is obtained. However, in the case of the potting method, the surface of the liquid resin does not become flat due to surface tension and does not align flush with the surface of the cover glass 18. For example, in the case of the potting method, the resin 17 has an inclined surface TP inclined obliquely downward from the surface of the cover glass 18. Other processes of the second embodiment may be similar to the configuration of the first embodiment.

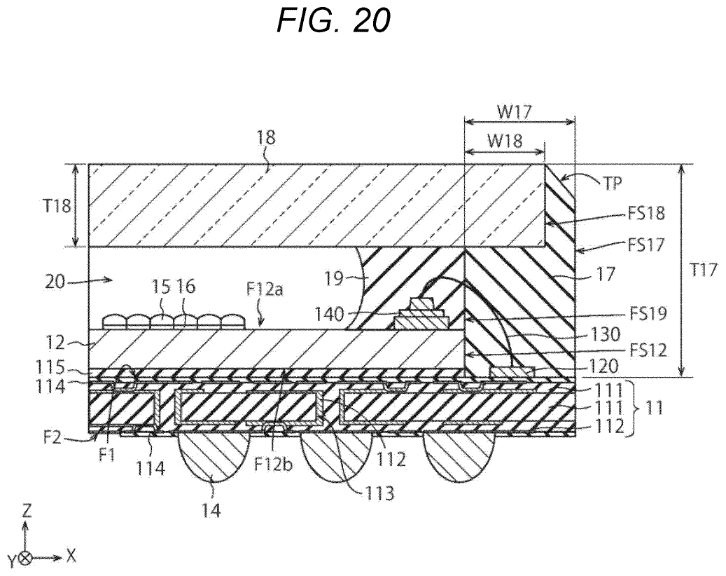

FIG. 20 is a cross-sectional view illustrating a configuration example of the solid-state imaging device 1 according to the second embodiment. As described above, even the resin 17 formed by the potting method can obtain the effects similar to the effects described with reference to FIGS. 7 to 10. Note that since the side surface FS18 of the cover glass 18 is covered with the resin 17, an effect of suppressing flare is obtained.

### Application Example to Mobile Body

The technology according to the present disclosure (present technology) can be applied to various products. For example, the technology of the present disclosure may be achieved in the form of a device to be mounted on a mobile object of any kind, such as an automobile, an electric vehicle, a hybrid electric vehicle, a motorcycle, a bicycle, a personal mobility, an airplane, a drone, a vessel, or a robot.

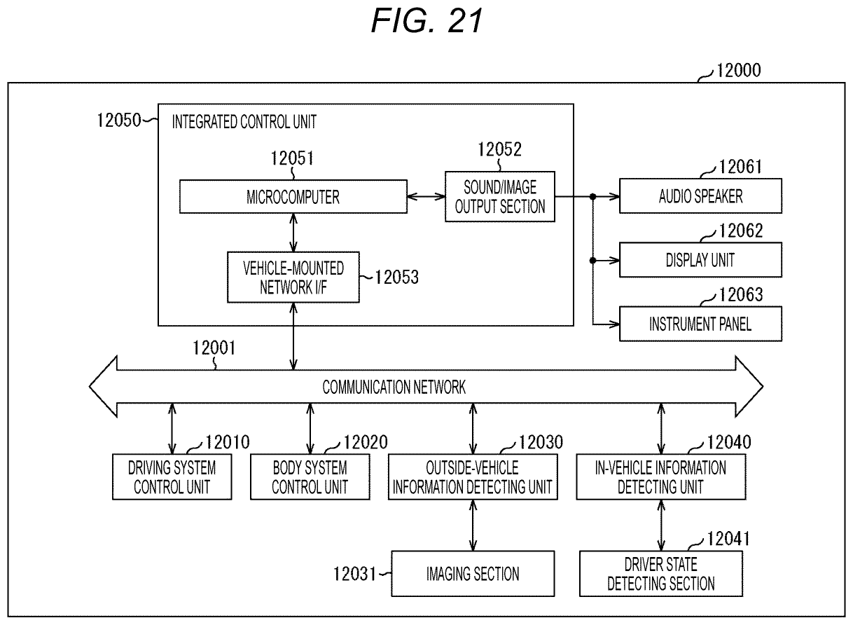

FIG. 21 is a block diagram illustrating an example of schematic configuration of a vehicle control system as an example of a mobile body control system to which the technology according to the present disclosure can be applied.

The vehicle control system 12000 includes a plurality of electronic control units connected to each other via a communication network 12001. In the example illustrated in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

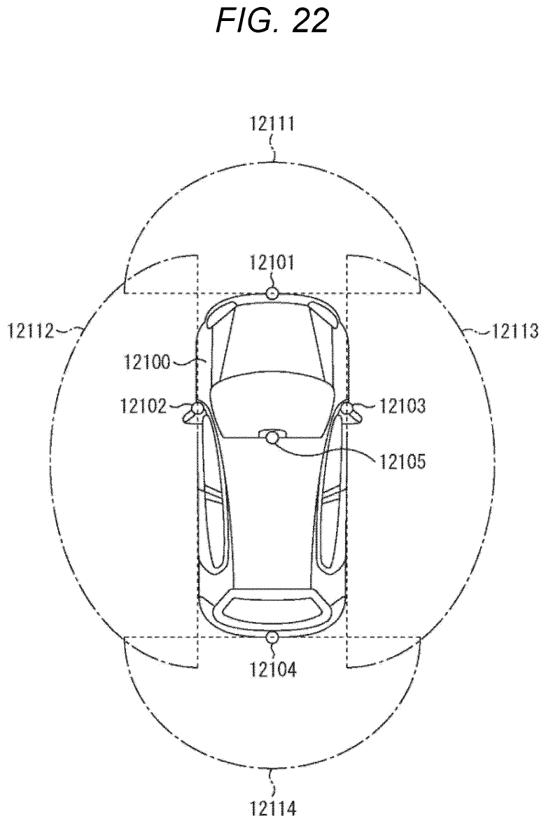

FIG. 22 is a diagram illustrating an example of an installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that, FIG. 22 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the configurations described above.

Note that the present technology can also employ the following configurations.

(1)

A solid-state imaging device including:
a photoelectric conversion element that has a light receiving surface;
a glass member that is provided above the light receiving surface; and
a first resin member that covers a side surface of the photoelectric conversion element and a side surface of the glass member, in which
an area of the photoelectric conversion element is 59 mm² or more in a plan view viewed from a first direction substantially perpendicular to the light receiving surface,
the glass member protrudes from the photoelectric conversion element by a first width of 15% to 93% of a width of the first resin member in a second direction substantially parallel to the light receiving surface, and
a thickness of the glass member is 40% or more of a thickness of the first resin member in the first direction.
   (2)

The solid-state imaging device according to (1), in which the side surface of the glass member is covered with the first resin member.

(3)

The solid-state imaging device according to (1) or (2), in which the thickness of the glass member is equal to or less than the thickness of the first resin member.

(4)

The solid-state imaging device according to any one of (1) to (3), further including: a second resin member that is provided between the glass member and the photoelectric conversion element at an outer edge of the photoelectric conversion element and forms a space between the glass member and the photoelectric conversion element.

(5)
The solid-state imaging device according to (4), in which the first and second resin members are provided on an entire outer edge of the photoelectric conversion element and seal the space.
   (6)
The solid-state imaging device according to any one of (1) to (5), in which the glass member protrudes from the photoelectric conversion element by the first width in the second direction over an entire outer edge of the photoelectric conversion element.
   (7)

The solid-state imaging device according to any one of (1) to (6), in which the thickness of the glass member is 40% or more of the thickness of the first resin member in the first direction over an entire outer edge of the photoelectric conversion element.

(8)

The solid-state imaging device according to any one of (1) to (7), further including:
a wiring substrate on which the photoelectric conversion element is mounted on a first surface, in which
the first resin member is provided on a surface of the wiring substrate so as to surround a periphery of the photoelectric conversion element.
   (9)

The solid-state imaging device according to (8), further including: a metal bump that is provided on a second surface of the wiring substrate opposite to the first surface.

(10)

The solid-state imaging device according to (8) or (9), further including: a metal wire that electrically connects a wiring of the wiring substrate and the photoelectric conversion element, in which
the metal wire is covered with the first resin member.

Note that the present disclosure is not limited to the above-described embodiments, and various modifications can be made without departing from the gist of the present disclosure. Furthermore, the effects described in the present description are merely examples and are not limited, and other effects may be provided.

### REFERENCE SIGNS LIST

1 Solid-state imaging device
11 Wiring substrate
12 Semiconductor chip
14 Metal bump
15 Color filter
16 On-chip lens
17 Mold resin
18 Cover glass
19 Seal member
111 Insulating layer
112 Wiring layer

1. A solid-state imaging device comprising:
a photoelectric conversion element that has a light receiving surface;
a glass member that is provided above the light receiving surface; and
a first resin member that covers a side surface of the photoelectric conversion element and a side surface of the glass member, wherein
an area of the photoelectric conversion element is 59 mm² or more in a plan view viewed from a first direction substantially perpendicular to the light receiving surface,
the glass member protrudes from the photoelectric conversion element by a first width of 15% to 93% of a width of the first resin member in a second direction substantially parallel to the light receiving surface, and
a thickness of the glass member is 40% or more of a thickness of the first resin member in the first direction.

2. The solid-state imaging device according to claim 1, wherein the side surface of the glass member is covered with the first resin member.

3. The solid-state imaging device according to claim 1, wherein the thickness of the glass member is equal to or less than the thickness of the first resin member.

4. The solid-state imaging device according to claim 1, further comprising: a second resin member that is provided between the glass member and the photoelectric conversion element at an outer edge of the photoelectric conversion element and forms a space between the glass member and the photoelectric conversion element.

5. The solid-state imaging device according to claim 4, wherein the first and second resin members are provided on an entire outer edge of the photoelectric conversion element and seal the space.

6. The solid-state imaging device according to claim 1, wherein the glass member protrudes from the photoelectric conversion element by the first width in the second direction over an entire outer edge of the photoelectric conversion element.

7. The solid-state imaging device according to claim 1, wherein the thickness of the glass member is 40% or more of the thickness of the first resin member in the first direction over an entire outer edge of the photoelectric conversion element.

8. The solid-state imaging device according to claim 1, further comprising:
a wiring substrate on which the photoelectric conversion element is mounted on a first surface, wherein
the first resin member is provided on a surface of the wiring substrate so as to surround a periphery of the photoelectric conversion element.

9. The solid-state imaging device according to claim 8, further comprising: a metal bump that is provided on a second surface of the wiring substrate opposite to the first surface.

10. The solid-state imaging device according to claim 8, further comprising: a metal wire that electrically connects a wiring of the wiring substrate and the photoelectric conversion element, wherein
the metal wire is covered with the first resin member.
